(19) United States
(12) Patent Application Publication
(10) Pub. No.: US 2025/0246426 A1
(43) Pub. Date: Jul. 31, 2025

(54) GROWTH OF THIN OXIDE LAYER IN VERTICAL CHANNEL STRUCTURE

(71) Applicant: Applied Materials, Inc., Santa Clara, CA (US)

(72) Inventors: Zhijun CHEN, San Jose, CA (US); Hoi-Sung CHUNG, Sunnyvale, CA (US); Fredrick FISHBURN, Aptos, CA (US); Raghuveer Satya MAKALA, Santa Clara, CA (US); Balasubramanian PRANATHARTHIHARAN, Santa Clara, CA (US)

(21) Appl. No.: 18/982,464

(22) Filed: Dec. 16, 2024

Related U.S. Application Data
(60) Provisional application No. 63/625,251, filed on Jan. 25, 2024.

(51) Int. Cl. H01L 21/02; H01L 21/67; H10D 62/00; H10D 62/17

(52) U.S. Cl. CPC H01L 21/0214; H01L 21/0206; H01L 21/02164; H01L 21/02238; H01L 21/02247; H01L 21/02252; H01L 21/02532; H01L 21/67213; H10D 62/01; H10D 62/235

(57) ABSTRACT

A method for forming an oxide layer in a vertical channel structure includes performing a pre-clean process to remove contaminants on exposed surfaces of channel pillars extending in a first direction, performing a silicon layer formation process to form a silicon layer on the exposed surfaces of the channel pillars, and performing a thermal oxidation process to convert the silicon layer to an oxide layer.

### CROSS-REFERENCE TO RELATED APPLICATIONS

This application claims priority to U.S. Provisional Application Ser. No. 63/625,251 filed Jan. 25, 2024, which is herein incorporated by reference in its entirety.

### BACKGROUND

### Field

Embodiments described herein generally relate to semiconductor device fabrication, and more particularly, to methods of forming a high quality thin oxide layer in a vertical channel structure.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, a vertical channel structure used in 4F² (feature square) dynamic random access memory (DRAM) devices may include thin silicon channel pillars having a thickness of about less than 10 nm and require a gate oxide layer that is thin and reliable.

Conventional methods of forming an oxide layer in such structures suffer from one or more of two issues. The first issue is high silicon consumption for thermal oxidation growth. That is, direct oxidation of silicon channel pillars causes high silicon loss and thus not desired for device scaling. The second issue is low quality of a formed oxide layer by atomic layer deposition (ALD) followed by densification treatment, which may include defects and traps within, thus leading to reduced device reliability.

Thus, there is a need for improved processes for forming a thin high quality oxide layer on thin silicon channel pillars and repairing the silicon channel pillars in a vertical channel structure, minimizing silicon consumption and defects in the formed oxide layer.

### SUMMARY

Embodiments of the present disclosure provide a method for forming an oxide layer in a vertical channel structure. The method includes performing a pre-clean process to remove native oxide and/or contaminants on exposed surfaces of a plurality of channel pillars extending in a first direction and exposed surfaces of a substrate on which the plurality of channel pillars are formed, performing a silicon layer formation process to form a silicon layer on the exposed surfaces of the plurality of channel pillars and the exposed surfaces of the substrate, and performing a thermal oxidation process to convert the silicon layer to an oxide layer.

Embodiments of the present disclosure also provide a multi-chamber cluster tool. The multi-chamber cluster tool includes a first processing chamber, a second processing chamber, a third processing chamber, and a controller configured to cause the multi-chamber cluster tool to perform, in the first processing chamber, a pre-clean process to remove native oxide and/or contaminants on exposed surfaces of a plurality of channel pillars extending in a first direction and exposed surfaces of a substrate on which the plurality of channel pillars are formed, perform, in the second processing chamber, a silicon layer formation process to form a silicon layer on the exposed surfaces of the plurality of channel pillars and the exposed surfaces of the substrate, and perform, in the third processing chamber, a thermal oxidation process to convert the silicon layer to an oxide layer.

Embodiments of the present disclosure further provide a vertical channel structure. The vertical channel structure includes a plurality of channel pillars extending in a first direction formed on a substrate, each channel pillar of the plurality of channel pillars having a thickness in a second direction orthogonal to the first direction of less than 10 nm and a width in a third direction orthogonal to the first and second directions of between 4 nm and 50 nm, and a gate oxide layer on surfaces of the plurality of channel pillars and surfaces of the substrate, the gate oxide layer having a thickness of 20 Å and 100 Å.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a multi-chamber cluster tool according to one embodiment.

FIG. 2 is a process flow diagram of a method of forming an oxide layer in a semiconductor structure according to one embodiment.

FIGS. 3A, 3A′, 3B, 3B′, 3C, and 3C′ are schematic views of a vertical channel structure according to one embodiment.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

Embodiments described herein are directed to methods of forming a high quality thin oxide layer in a vertical channel structure used in a 4F² dynamic random access memory (DRAM) device. A thin oxide layer that may be used as a gate oxide layer on thin silicon channel pillars in such devices may be formed by first depositing a thin silicon layer on exposed surfaces of silicon channel pillars and then oxidizing the thin silicon layer by a thermal oxidation process. The thin oxide layer may be formed by epitaxial deposition or a combination of a thin silicon dioxide (SiO2) interfacial layer formation and a silicon (Si) conformal deposition.

The methods described herein for forming a thin oxide layer may reduce silicon consumption and increase quality of the formed oxide layer in a vertical channel structure, thus enabling a gate oxide scaling with improved reliability.

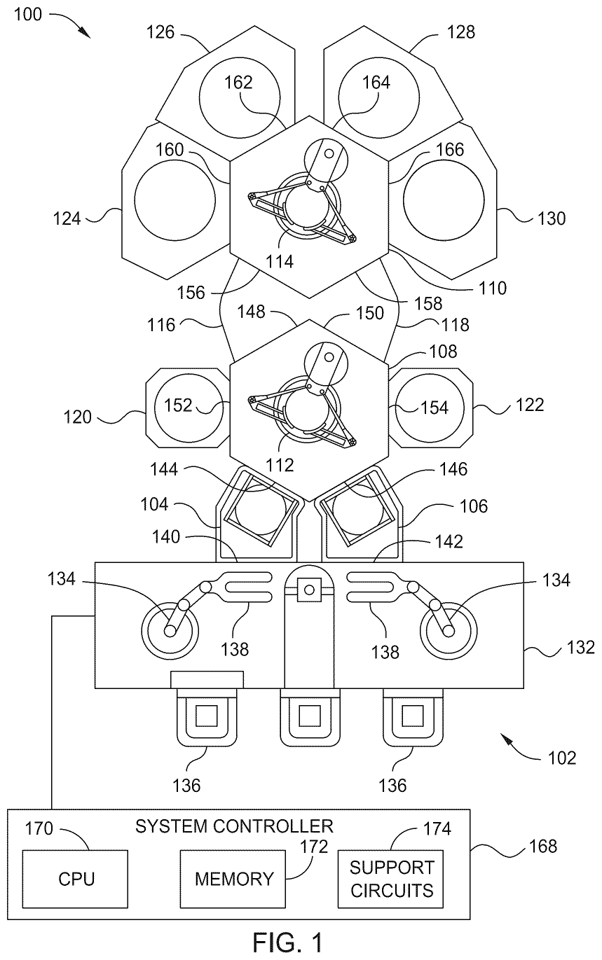

FIG. 1 is a schematic top view of a multi-chamber cluster tool 100, according to one or more embodiments of the present disclosure. The multi-chamber cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber cluster tool 100 can be processed in and transferred between the various chambers without exposing the substrates to an ambient environment exterior to the multi-chamber cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber cluster tool 100. Accordingly, the multi-chamber cluster tool 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

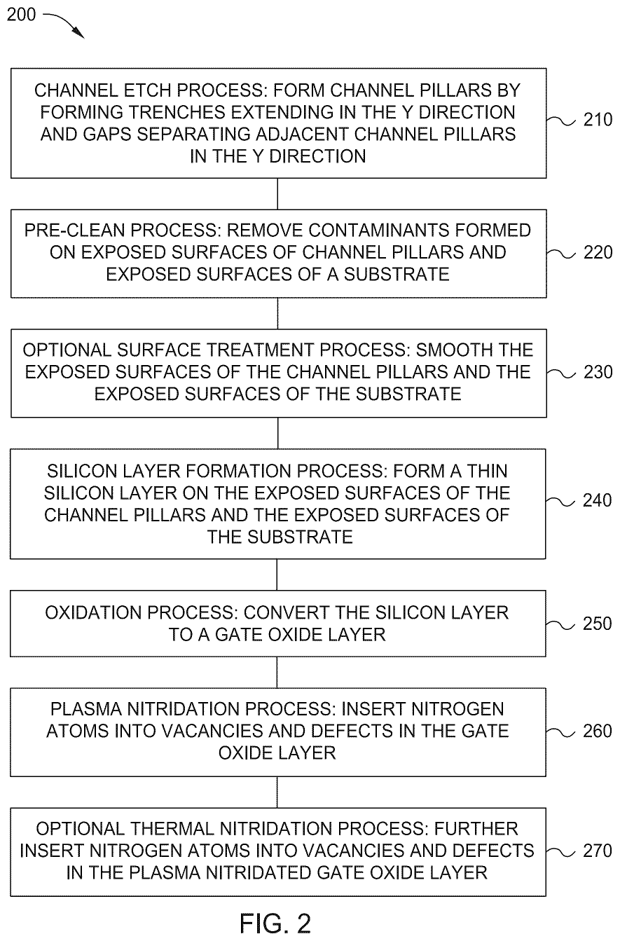

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be an Aktiv™ Pre-clean (APC) chamber, a Pre-clean XT (MCxT-2) chamber, or a SiCoNi™ Pre-clean chamber, available from Applied Materials of Santa Clara, Calif. The processing chamber 124, 126, 128, or 130 may be a Centura™ Epi chamber, a Volta™ CVD/ALD chamber, an Encore™ PVD chamber, a selective tungsten deposition chamber, an ionized metal plasma physical vapor deposition (IMP PVD) chamber, a rapid thermal process (RTP) chamber, or a plasma etch (PE) chamber, available from Applied Materials of Santa Clara, Calif. A system controller 168 is coupled to the multi-chamber cluster tool 100 for controlling the multi-chamber cluster tool 100 or components thereof. For example, the system controller 168 may control the operation of the multi-chamber cluster tool 100 using a direct control of the chambers 104, 106, 108, 110, 116, 118, 120, 122, 124, 126, 128, 130 of the multi-chamber cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber cluster tool 100. The system controller 168 is configured to cause the chambers 104, 106, 108, 110, 116, 118, 120, 122, 124, 126, 128, 130 of the multi-chamber cluster tool 100 to perform all of the operations described with respect to FIG. 2.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

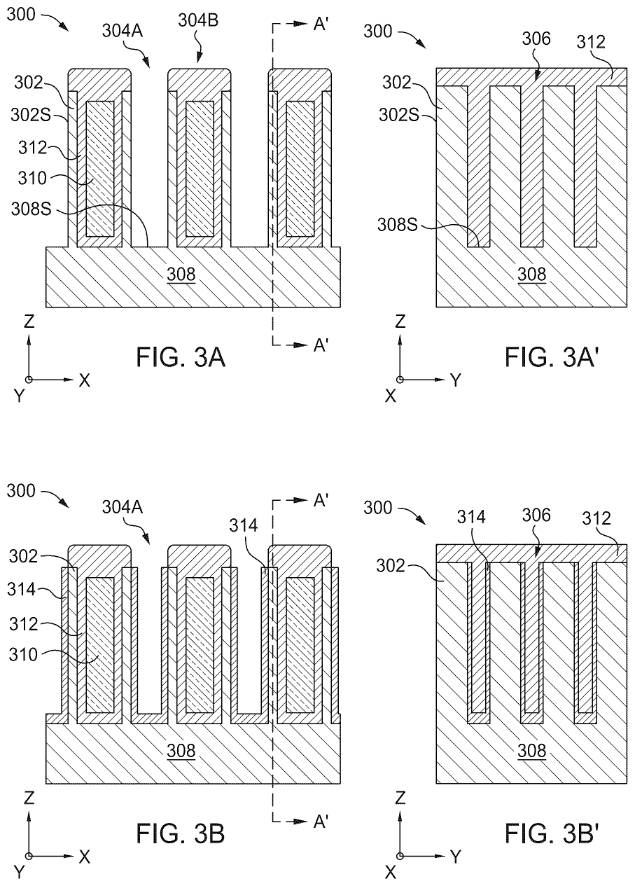

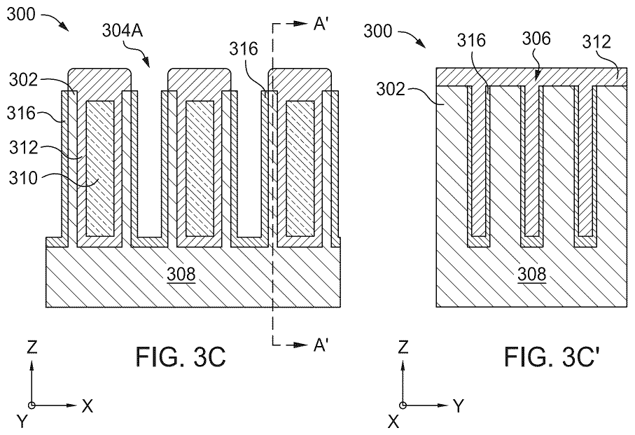

FIG. 2 is a process flow diagram of a method 200 of forming an oxide layer in a vertical channel structure 300, according to one or more implementations of the present disclosure. FIGS. 3A, 3B, and 3C are cross-sectional views of a portion of the vertical channel structure 300 corresponding to various stages of the method 200. FIGS. 3A′, 3B′, and 3C′ are cross-sectional views of the vertical channel structure 300 along the line A′-A′ shown in FIGS. 3A, 3B, and 3C. The vertical channel structure 300 may be a vertical channel transistor portion of a 4F² dynamic random access memory (DRAM) device. Additionally, the method 200 may be used to form vertical channel structures having different configurations or other semiconductor devices, such as nanowires, that require a high-quality thin oxide layer. Further, it should also be understood that the operations depicted in FIG. 2 may be performed simultaneously and/or in a different order than the order depicted in FIG. 2.

The method 200 begins in block 210, in which a channel etch process is performed to form channel pillars 302 by forming trenches 304A and 304B extending in the Y direction and gaps 306 separating adjacent channel pillars 302 in the Y direction, in a substrate 308, by appropriate lithography and etch processes, as shown in FIGS. 3A and 3A′. In the trenches 304B between adjacent channel pillars 302 in the X direction, an element 310 encapsulated by a dielectric layer 312 is formed by an appropriate deposition process.

In some implementations, the substrate 308 may have a substantially planar surface, an uneven surface, or a substantially planar surface having a structure formed thereon. The substrate 308 may be a material such as crystalline silicon (e.g., Si<100> or Si<111>), doped or undoped polysilicon, doped or undoped silicon wafers and patterned or non-patterned wafers silicon on insulator (SOI), carbon doped silicon oxides, silicon nitride, doped silicon, germanium, gallium arsenide, glass, or sapphire. The substrate 308 may have various shapes and dimensions, such as 200 mm or 300 mm diameter wafers and rectangular or square panels. Unless otherwise noted, implementations and examples described herein refer to substrates having a 300 mm diameter. In some implementations, the substrate 308 may be a crystalline silicon substrate (e.g., monocrystalline silicon or polycrystalline silicon).

The trenches 304A may each have a width in the X direction of between about 10 nm and about 30 nm. The gaps 306 may each have a width in the Y direction of between about 5 nm and about 30 nm. The channel pillars 302 may be formed of silicon (Si), and each having a thickness in the X direction of less than about 10 nm, a width in the Y direction of between about 4 nm and about 50 nm, and a height in the Z direction of between about 50 nm and about 300 nm. The element 310 may be a gate electrode formed of poly-silicon (Si), titanium nitride (TiN), tungsten (W), molybdenum (Mo), ruthenium (Ru), or a combination thereof. The element 310 may be a dielectric fill or an air gap. The dielectric layer 312 may be formed of silicon dioxide (SiO₂), silicon nitride (Si₃N₄), or silicon oxynitride (SiOₓN_{y}), silicon oxycarbonitride (SiOCN), silicon oxycarbide (SiOC), aluminum oxide (Al₂O₃), hafnium oxide (HfO₂), zirconium oxide (ZrO₂), or a combination thereof.

In block 220, in which a pre-clean process is performed to remove contaminants, such as carbon-containing contaminants (e.g., patterning residues), oxide-containing contaminants (e.g., native oxide layers), or halide-containing contaminants (e.g., residues from a reactive ion etching (RIE)) formed on exposed surfaces 308S of the channel pillars 302 and exposed surfaces 308S of the substrate 308 in the lithography and etch process to form the channel pillars 302. The pre-cleaning process may be performed in a processing chamber, such as the processing chamber 122 shown in FIG. 1.

The pre-cleaning process to remove carbon-containing contaminants may include a reactive ion etching (RIE) process, using a plasma formed from a gas including hydrogen (H), argon (Ar), helium (He), or a combination thereof, a wet etch process, a plasma ashing process, a thermal ashing process, or any other appropriate process.

The pre-cleaning process to remove oxide-containing contaminants may include an isotropic plasma etch process, such as a dry chemical etch process, using amorphous hydrofluoric acid (HF) and ammonia (NH₃), or a SiCoNi™ dry etch process, using a plasma formed from a gas including ammonia (NH₃), or nitrogen trifluoride (NF₃), or a wet etch process. The dry etch process is selective for oxide layers, and thus does not readily etch silicon, germanium, or nitride layers regardless of whether the layers are amorphous, crystalline or polycrystalline.

The pre-cleaning process to remove oxide-containing contaminants may be performed prior to or subsequent to the pre-cleaning process to remove carbon-containing contaminants.

In some embodiments, a silicon trim process is performed to laterally etch the channel pillars 302 in the X direction, by appropriate etch process. The silicon trim process removes damaged silicon (Si) layers from prior process steps.

In some embodiments, an oxidation process is performed to oxidize the exposed surfaces 308S of the channel pillars 302 and exposed surfaces 308S of the substrate prior to the pre-cleaning process to remove oxide-containing contaminants. This oxidation process removes plasma damaged surfaces of the channel pillars 302 that will be replaced with an epitaxially grown silicon layer 314 in the silicon layer formation process in block 240.

In block 230, an optional surface treatment process is performed to improve smoothness of the exposed surfaces 302S of the channel pillars 302 and the exposed surfaces 302S of the substrate. The surface treatment process may include a thermal treatment process (e.g., hydrogen (H₂) bake), a rapid thermal process (RTP), or a plasma treatment process, performed in a pre-clean chamber, such as the processing chamber 122 shown in FIG. 1. In the plasma treatment process, the surfaces 302S of the channel pillars 302 and the surfaces 308S of the substrate 308 are exposed to a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas (e.g., helium (He), argon (Ar)), or any combination thereof.

In block 240, a silicon layer formation process to form a thin silicon layer 314 on the exposed surfaces 302S of the channel pillars 302 and the exposed surfaces 302S of the substrate 202, as shown in FIGS. 3B and 3B′. In some embodiments, the thin silicon layer 314 is an epitaxial layer of silicon (Si) formed by a selective epitaxial deposition process. The selective epitaxial deposition process may be performed in a processing chamber, such as the processing chamber 126, 128, or 130 shown in FIG. 1.

The silicon layer 314 may be formed of silicon (Si) having a thickness of between about 10 Å and about 50 Å.

The selective epitaxial deposition process may include a conformal epitaxial deposition process and an etch process. In the epitaxial deposition process in which the vertical channel structure 300 is exposed to a deposition gas, an amorphous layer of silicon (Si) may be formed on surfaces of the dielectric layers 312 (e.g., silicon dioxide (SiO₂) or silicon nitride (Si₃N₄)), while an epitaxial layer of silicon (Si) may be formed on the exposed surfaces 302S of the channel pillars 302 and the exposed surfaces 308S of the substrate 308 (e.g., silicon (Si)). In the subsequent etch process, the amorphous layer can be etched at a faster rate than the epitaxial layer, by an appropriate etching gas. Thus, an overall result of the epitaxial deposition process and the etch process combined can be a selective epitaxial growth on the surfaces 302S of the channel pillars 302 and the surfaces 308S of the substrate 308, while minimizing growth, if any, on the surface of the dielectric layers 312.

In some embodiments, the deposition gas includes a silicon-containing precursor, a carrier gas, and an optional dopant source. The silicon-containing precursor may include silane (SiH₄), disilane (Si₂H₆), dichlorosilane (SiH₂Cl₂), tetrasilane (Si₄H₁₀), or a combination thereof. In the selective epitaxial deposition process, the etching gas includes an etchant gas and a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), hydrogen (H₂), or nitrogen (N₂). Optional dopant source can be n-type, e.g. phosphine (PH₃) and arsine (AsH₃), or p-type, e.g. diborane (B₂H₆) and boron trichloride (BCl₃).

The epitaxial deposition process may be performed at a temperature of between about 350° C. and about 450° C. and at a pressure of between about 5 Torr and about 600 Torr, or at a temperature of between about 600° C. and about 800° C. and a pressure of below about 600 Torr.

A cycle of the epitaxial deposition and etch processes may be repeated as needed to obtain a desired thickness of the silicon layer 314.

In some embodiments, alternative to the epitaxial deposition process, a silicon layer 314 is formed by an interface formation process and a conformal deposition process. The interface formation process forms an interfacial layer of amorphous silicon oxide (SiO₂), having a thickness of between about 3 Å and about 20 Å, for example, about 5 Å, corresponding to one or more monolayers of silicon oxide, on the exposed surfaces 308S of the channel pillars 302 and the exposed surfaces 308S of the substrate 308. The conformal deposition process deposits a silicon layer 314 of the interfacial layer.

The interface formation process may include a suitable thermal oxidation process, such as an enhanced in-situ steam generation (eISSG) process utilizing nitrous oxide (N₂O) gas, a radical oxidation process utilizing hydrogen (H₂) and oxygen (O₂) gases, or a rapid thermal oxidation (RTO) process utilizing oxygen (O₂) gas, performed in a processing chamber, such as the processing chamber 120, 122, 124, 126, 128, or 130 shown in FIG. 1. The interfacial layer may act as a nucleation layer of a silicon layer 314 to be deposited thereon and improve quality (e.g., such as interface state density, accumulation capacitance, frequency dispersion, and leakage current) of the interface between the substrate 308 and the gate oxide layer 316 to be formed.

The deposition process may be any appropriate deposition process, such as atomic layer deposition (ALD), epitaxial deposition, chemical vapor deposition (CVD), physical vapor deposition (PVD), or the like performed in a processing chamber, such as the processing chamber 126, 128, or 130 shown in FIG. 1.

In block 250, a thermal oxidation process is performed, in which the silicon layer 314 is oxidized to convert the silicon layer 314 to a gate oxide layer 316, as shown in FIGS. 3C and 3C′. The gate oxide layer 316 may be formed of silicon dioxide (SiO₂).

The thermal oxidation process may include a radical oxidation process utilizing H₂ and O₂ gases, or a rapid thermal oxidation (RTO) process utilizing O₂ gas. The thermal oxidation process may be performed in a processing chamber, such as the processing chamber 126, 128, or 130 shown in FIG. 1. The thermal oxidation process may not change a thickness of the silicon layer 314, and thus the gate oxide layer 316 may have a thickness of between about 10 Å and about 100 Å.

In some embodiments, alternative to the thermal oxidation process, a silicon oxide (SiO₂) layer is deposited on the silicon layer 314 formed in the silicon layer formation process in block 240, with or without an interfacial layer of amorphous silicon oxide (SiO₂), and densified into the gate oxide layer 316. The deposition process to deposit a silicon oxide (SiO₂) layer may be any appropriate deposition process, such as atomic layer deposition (ALD), chemical vapor deposition (CVD), or the like performed in a processing chamber, such as the processing chamber 126, 128, or 130 shown in FIG. 1. The densification of the silicon oxide (SiO₂) layer is performed by a plasma treatment, such as a decoupled plasma (DPHe) process and a remote plasma oxidation (RPO2) process.

In block 260, an optional plasma nitridation process is performed to insert nitrogen atoms into vacancies and defects in the gate oxide layer 316. The plasma nitridation process may be a plasma treatment process, such as decoupled plasma nitridation (DPN) process, a decoupled plasma (DPX) process, a decoupled plasma plus (DPX+) process, or a rapid thermal nitridation (RTN) process performed in a processing chamber, such as the processing chambers 120, 122, 124, 126, 128, and 130 shown in FIG. 1. The plasma nitridation process exposes the gate oxide layer 316 to nitrogen plasma, which may allow nitrogen radicals or nitrogen atoms to be incorporated within the gate oxide layer 316, on the top surface, throughout the thickness, or at the interface of the gate oxide layer 316. During the plasma nitridation process, nitrogen atoms may form metastable bonds with oxygen (O). Gases that may be used in the plasma process include nitrogen containing gas, such as nitrogen (N₂), ammonia (NH₃), or mixtures thereof. In one example, the nitrogen gas is ammonia (NH₃) mixed with about 3% to about 8% of nitrogen (N₂). The plasma nitridation process may or may not change a thickness of the gate oxide layer 316 as a result of the nitrogen incorporation to vacancies and defects in the as-deposited gate oxide layer 316.

The plasma nitridation process may be performed for between about 4 seconds and about 300 seconds, at a temperature of between about room temperature and about 1200° C.

In block 270, an optional thermal nitridation process is performed to stabilize nitrogen atoms into vacancies and defects in the plasma nitridated gate oxide layer 316 and regrow a surface of the gate oxide layer 316. The thermal nitridation process may include a thermal anneal process, performed in a rapid thermal processing (RTP) chamber, such as RADOX™ chamber, available from Applied Materials, Inc., located in Santa Clara, Calif. The RTP chamber may be any of the processing chambers 120, 122, 124, 126, 128, and 130 shown in FIG. 1.

In the embodiments described herein, the pre-clean process in block 220, the surface treatment process in block 230, the silicon layer formation process in block 240, the thermal oxidation process in block 250, the plasma nitridation process in block 270, and the thermal nitridation process in block 270 may be performed in a multi-chamber cluster tool, such as the multi-chamber cluster tool 100, shown in FIG. 1, without vacuum break.

In the embodiments described herein methods of forming a high quality thin oxide layer in a semiconductor device, such as a vertical channel structure used in a 4F² dynamic random access memory (DRAM) device, and a thin nanowire thin nanowire field-effect-transistor (FET), are provided. In the methods described herein, a thin oxide layer may be formed by first depositing a thin silicon layer on exposed surfaces of silicon channel pillars and then oxidizing the thin silicon layer by a thermal oxidation process.

The methods described herein for forming a thin oxide layer may reduce silicon consumption and increase quality of the formed oxide layer in a vertical channel structure, thus enabling a gate oxide scaling with improved reliability.

While the foregoing is directed to embodiments of the present disclosure, other and further embodiments of the disclosure may be devised without departing from the basic scope thereof, and the scope thereof is determined by the claims that follow.

1. A method for forming an oxide layer in a vertical channel structure, comprising:
performing a pre-clean process to remove native oxide and/or contaminants on exposed surfaces of a plurality of channel pillars extending in a first direction and exposed surfaces of a substrate on which the plurality of channel pillars are formed;
performing a silicon layer formation process to form a silicon layer on the exposed surfaces of the plurality of channel pillars and the exposed surfaces of the substrate; and
performing a thermal oxidation process to convert the silicon layer to an oxide layer.

2. The method of claim 1, wherein:
each channel pillar of the plurality of channel pillars has a thickness in a second direction orthogonal to the first direction of less than 10 nm and a width in a third direction orthogonal to the first and second directions of between 4 nm and 50 nm, and
the silicon layer has a width of between 10 Å and 50 Å.

3. The method of claim 1, wherein the pre-clean process, the silicon layer formation process, and the thermal oxidation process are performed without vacuum break.

4. The method of claim 1, wherein the silicon layer formation process comprises a selective epitaxial deposition process comprising a conformal epitaxial deposition process and an etch process.

5. The method of claim 1, wherein the silicon layer formation process comprises:
an interface formation process to form an interfacial layer of amorphous silicon oxide (SiO₂), having a thickness of between 3 Å and 20 Å on the exposed surfaces of the plurality of channel pillars and the exposed surfaces of the substrate; and
a conformal deposition process to deposit the silicon layer on the interfacial layer.

6. The method of claim 1, further comprising:
performing a surface treatment process to improve smoothness of the exposed surfaces of the plurality of channel pillars and the exposed surfaces of the substrate, wherein the surface treatment process comprises:
a thermal treatment process;
a rapid thermal process; or
a plasma treatment process comprising using a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas, or any combination thereof.

7. The method of claim 1, wherein the thermal oxidation process comprises a radical oxidation process utilizing hydrogen (H₂) and oxygen (O₂) gases, or a rapid thermal oxidation (RTO) process utilizing oxygen (O₂) gas.

8. The method of claim 1, further comprising:
performing a plasma nitridation process to insert nitrogen atoms into vacancies and defects in the oxide layer.

9. The method of claim 8, wherein the plasma nitridation process comprises exposing the oxide layer to nitrogen plasma using nitrogen containing gas.

10. The method of claim 8, further comprising:
performing a thermal anneal process to stabilize nitrogen atoms into vacancies and defects in the plasma nitridated oxide layer and regrow a surface of the oxide layer.

11. A multi-chamber cluster tool comprising:
a first processing chamber;
a second processing chamber;
a third processing chamber; and
a controller configured to cause the multi-chamber cluster tool to:
perform, in the first processing chamber, a pre-clean process to remove native oxide and/or contaminants on exposed surfaces of a plurality of channel pillars extending in a first direction and exposed surfaces of a substrate on which the plurality of channel pillars are formed;
perform, in the second processing chamber, a silicon layer formation process to form a silicon layer on the exposed surfaces of the plurality of channel pillars and the exposed surfaces of the substrate; and
perform, in the third processing chamber, a thermal oxidation process to convert the silicon layer to an oxide layer.

12. The multi-chamber cluster tool of claim 11, wherein:
each channel pillar of the plurality of channel pillars has a thickness in a second direction orthogonal to the first direction of less than 10 nm and a width in a third direction orthogonal to the first and second directions of between 4 nm and 50 nm, and
the silicon layer has a width of between 10 Å and 50 Å.

13. The multi-chamber cluster tool of claim 11, wherein the pre-clean process, the silicon layer formation process, and the thermal oxidation process are performed without vacuum break.

14. The multi-chamber cluster tool of claim 11, wherein the silicon layer formation process comprises a selective epitaxial deposition process and an etch process.

15. The multi-chamber cluster tool of claim 11, wherein the silicon layer formation process comprises:
an interface formation process to form an interfacial layer of amorphous silicon oxide (SiO₂), having a thickness of between 3 Å and 20 Å on the exposed surfaces of the plurality of channel pillars and the exposed surfaces of the substrate; and
a conformal deposition process to deposit the silicon layer on the interfacial layer.

16. The multi-chamber cluster tool of claim 11, wherein the thermal oxidation process comprises a radical oxidation process utilizing hydrogen (H₂) and oxygen (O₂) gases, or a rapid thermal oxidation (RTO) process utilizing oxygen (O₂) gas.

17. The multi-chamber cluster tool of claim 11, further comprising:
a fourth processing chamber, wherein the controller is further configured to cause the multi-chamber cluster tool to:
perform, in the third processing chamber, a surface treatment process to improve smoothness of the exposed surfaces of the plurality of channel pillars and the exposed surfaces of the substrate, wherein the surface treatment process comprises:
a thermal treatment process;
a rapid thermal process; or
a plasma treatment process comprising using a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas, or any combination thereof.

18. The multi-chamber cluster tool of claim 17, further comprising:
a fifth processing chamber, wherein the controller is further configured to cause the multi-chamber cluster tool to:
perform, in the fifth processing chamber, a plasma nitridation process to insert nitrogen atoms into vacancies and defects in the oxide layer, wherein the plasma nitridation process comprises exposing the oxide layer to nitrogen plasma using nitrogen containing gas.

19. The multi-chamber cluster tool of claim 18, further comprising:
a sixth processing chamber, wherein the controller is further configured to cause the multi-chamber cluster tool to:
perform, in the sixth processing chamber, a thermal nitridation process to stabilize nitrogen atoms into vacancies and defects in the plasma nitridated oxide layer and regrow a surface of the oxide layer, wherein the thermal nitridation process comprises a thermal anneal process.

20. A vertical channel structure, comprising:
a plurality of channel pillars extending in a first direction formed on a substrate, each channel pillar of the plurality of channel pillars having a thickness in a second direction orthogonal to the first direction of less than 10 nm and a width in a third direction orthogonal to the first and second directions of between 4 nm and 50 nm; and
a gate oxide layer on surfaces of the plurality of channel pillars and surfaces of the substrate, the gate oxide layer having a thickness of 20 Å and 100 Å.
